(19) United States
(12) Patent Application Publication
(10) Pub. No.: US 2026/0122843 A1
(43) Pub. Date: Apr. 30, 2026

(54) MITIGATION OF COOLANT LEAKS IN LIQUID-COOLED INFORMATION HANDLING SYSTEMS

(71) Applicant: DELL PRODUCTS L.P., Round Rock, TX (US)

(72) Inventors: Sandor Farkas, Round Rock, TX (US); Michael Stumpf, Cedar Park, TX (US)

(21) Appl. No.: 18/927,885

(22) Filed: Oct. 26, 2024

(51) Int. Cl. H05K 7/20; B01J 20/26; B01J 20/28; G01N 21/64

(52) U.S. Cl. CPC H05K 7/20272; B01J 20/261; B01J 20/28023; G01N 21/64

(57) ABSTRACT

A leak mitigation system to mitigate coolant leaks within a liquid-cooled information handling system includes an absorption layer. The absorption layer is infused with a dye and is positioned within a chassis of the liquid-cooled information handling system. The absorption layer absorbs coolant leaked from a liquid cooling assembly within the chassis. The dye fluoresces in response to contact with the coolant. The leak mitigation system further includes an optical leak sensor (OLS) positioned within the chassis. The OLS is configured to detect the leaked coolant in response to fluorescence of the dye induced by contact with the leaked coolant when illuminated with ultraviolet light emitted by the OLS.

### FIELD OF THE DISCLOSURE

The present disclosure generally relates to information handling systems, and more particularly relates to liquid-cooled information handling systems.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A leak mitigation system for mitigating coolant leaks within a liquid-cooled information handling system includes an absorption layer. The absorption layer may be infused with dye and positioned within a chassis of the liquid-cooled information handling system. The absorption layer may absorb coolant leaked from a liquid cooling assembly within the chassis. The leak mitigation system further includes an optical leak sensor (OLS) positioned within the chassis. The OLS may detect the leaked coolant in response to fluorescence of the dye induced by contact with the leaked coolant in the presence of ultraviolet light emitted by the OLS.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is perspective view of an example liquid cooling assembly for an information handling system according to an embodiment of the present disclosure;

FIG. 2 is a block diagram of an example optical leak sensor (OLS) according to an embodiment of the present disclosure;

FIG. 3 is a side view of a leak mitigation system according to an embodiment of the present disclosure;

FIG. 4 is a perspective view of the leak mitigation system according to another embodiment of the present disclosure;

FIG. 5 is a perspective view of a device for mitigating coolant leaks within the chassis of a liquid-cooled information handling system according to an embodiment of the present disclosure;

FIG. 6 is a perspective view of a device for mitigating coolant leaks within the chassis of a liquid-cooled information handling system according to another embodiment of the present disclosure; and

FIG. 7 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or sub-system. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a personal computer (such as a desktop or laptop), server (such as a blade server or rack server), a network storage device, or any other suitable device and may vary in size, shape, performance, functionality, and price. The information handling system may include random access memory (RAM), one or more processing resources such as a central processing unit (CPU), graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

A liquid cooling apparatus for an information handling system may include a pump, tubing, heat exchanger, coolant port, one or more CPU cold plates, one or more GPU cold plates, a memory heatsink, and fan. Operatively, the pump circulates a coolant such as water or other liquid (e.g., water plus additives) through the tubing and heat exchanger to the components of the information handling system, including memory, one or more CPUs and/or one or more GPU, as well as other components. The coolant circulates in a closed loop within the housing of the information handling system and absorbs heat from the components to cool the components via the cold plates. Liquid cooling offers advantages over other types of cooling. Thus, as the processing power of information handling systems continues to increase, the use of liquid cooling is expected to become more common.

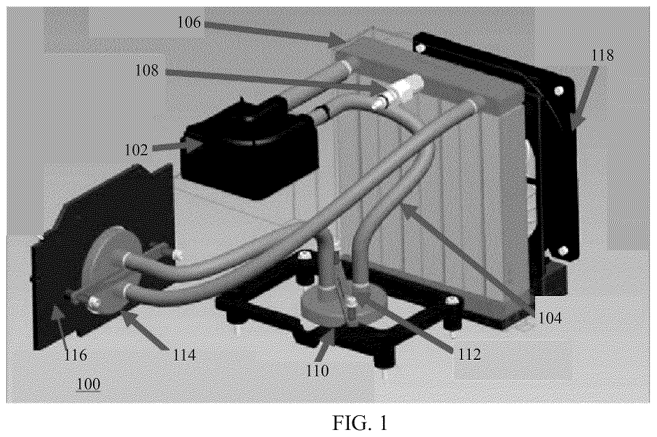

FIG. 1 illustrates an example liquid cooling assembly 100 according to at least one embodiment of the present disclosure. Liquid cooling assembly 100 illustratively includes pump 102, tubing 104, heat exchanger 106, coolant port 108, CPU cold plate 110, clamp 112, GPU cold plate 114, memory heatsink 116, and fan 118. Pump 102 circulates a coolant such as water or other liquid (e.g., water plus additives) through tubing 104 and heat exchanger 106 to the components of the information handling system, including memory, CPU and/or GPU, as well as other components. The coolant circulates in a closed loop within the housing of the information handling system and absorbs heat from the components to cool the components via the cold plates. Liquid cooling leverages the exceptional thermal capacity of liquid to absorb and remove heat created by new high-power processors. The cold plates may be attached directly to processors, enabling the coolant to capture and convey heat to a heat exchanger located, for example, in a rack or row. In a datacenter, for example, the heat load may be removed from the datacenter via a liquid loop, potentially bypassing the expensive chiller system. Replacing or supplementing conventional air-cooling with more-efficient liquid cooling may enhance the operational efficiency of the datacenter.

Notwithstanding the advantages of liquid cooling, there is the possibility that one or more components of the liquid cooling assembly may develop leaks over time due to vibration, thermal cycles, aging, misalignment of heat exchangers or cold plates, or the like. Any leak that exposes the components of the information handling system to liquid can cause corrosion or damage to the circuitry within the housing of information handling system 100. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack.

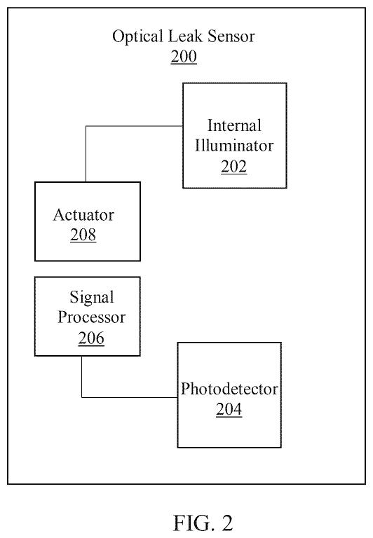

FIG. 2 is a front view of an example OLS 200 for detecting a coolant leak within an information handling system according to at least one embodiment of the present disclosure. OLS 200 illustratively includes internal illuminator 202, photodetector 204, and signal processor 206 communicatively coupled to photodetector 204. In certain embodiments, OLS 200 may also include actuator 208 for controlling internal illuminator 204. OLS 200, in certain arrangements, may be integrated into the motherboard of an information handling system. In other arrangements, OLS 200 may be a stand-alone device that connects internally to an information handling system, for example by connecting to an internal partition, side region, cover, or other part of the information handling system.

OLS 200 detects a potential leak within an information handling system based on the information conveyed by the nature of the light detected by photodetector 204 when light emitted by internal illuminator 202 is reflected to the photodetector. In certain embodiments, internal illuminator 202 includes one or more light emitting diodes (LEDs). The light emitted by internal illuminator 202 may have a specific wavelength or may form a spectrum of light having different frequencies and corresponding wavelengths. In certain embodiments, the emitted light is specifically ultraviolet (UV) light. As described below, the dye may fluoresce when illuminated by light, such as UV light, emitted by internal illuminator 202 and is detectable by photodetector 204. Actuator 208, included in certain embodiments, may intermittently activate internal illuminator 202, causing the internal illuminator to emit pulses of light in a predetermined pattern. In other embodiments, actuator 208 may cause internal illuminator 202 to emit a constant light emission.

Photodetector 204 includes one or more photodetectors, such as an array of photodiodes that are sensitive to different wavelengths of light and that are configured to determine color based on the ratio of reflected RGB light. In accordance with some embodiments, photodetector 204 can include RGB filters that capture the intensity of the primary colors, such that the combined data determines the color of the light. In other embodiments, photodetector 204 includes multiple, stacked photodetectors in which each layer is sensitive to a specific color. Photodetector 204, according to yet other embodiments, includes plasmonic grating that differentiates between light wavelengths and directs specific light colors into specific photodetectors without filtering.

Operatively, photodetector 204 is configured to absorb light across a color spectrum in response to the light being reflected from an object within the chassis of an information handling system. The object, for example, may be a CPU, GPU, memory, power supply unit, DIMM latch, internal wall of the chassis, or other component of the information handling system. The components may be part of a printed circuit board with expansion capabilities that makes up a motherboard or mainboard of the information handling system, such as information handling system 100 of FIG. 1, or the object may be an internal portion of the information handling system's chassis. The object may be an extraneous or foreign object. Of specific interest is an object formed by a collection of liquid coolant leaked from a liquid cooling apparatus or subsystem of the information handling system. Photodetector 204 converts the light reflected from an object into an electrical signal and conveys the electrical signal to signal processor 206 for processing.

When a coolant leak is detected, it is important to mitigate any damage that may be caused by the leak. An optimal, or near optimal, way of mitigating damage due to a leak is to minimize or contain the “blast radius” or initial area of the leak; that is, contain the flow of liquid to thereby reduce the spread of the liquid and limit the area affected.

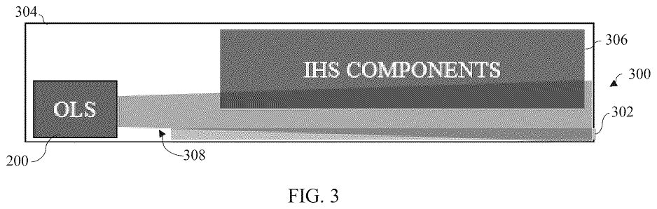

FIG. 3 is a side view of a leak mitigation system 300 according to at least one embodiment of the present disclosure. Leak mitigation system 300 illustratively includes absorption layer 302 and OLS 200. Both absorption layer 302 and OLS 200 are positioned within chassis 304 of an information handling system along with internal components 306 (e.g., CPU, GPU, memory) of the information handling system.

Absorption layer 302 may be covered by or infused with dye. OLS 200 is positioned to view objects along pathway 308 and is configured to detect visible light engendered by the fluorescing of the dye when coolant leaked from a liquid cooling assembly within chassis 304 comes in physical contact the dye in the presence of UV light emitted by OLS 200.

Not only does leak mitigation system 300 detect a leak, but it also prevents or mitigates potential damage to internal components 306 by absorbing the leaked coolant. In certain embodiments, absorption layer 302 is formed of a superabsorbent polymer (SAP), a highly absorbent material that absorbs and retains large amounts of liquid relative to its own mass. Absorption layer 302, in other embodiments, may be formed of other absorbent materials such as polypropylene-based synthetic fibers, cellulose-based natural fibers, and/or the like. Forming absorption layer 302 of an SAP, however, may offer certain unique advantages. For example, a SAP such as sodium polyacrylate, having the chemical formula [—CH₂—CH(CO₂Na)—]n and often referred to as “waterlock,” can absorb 100 to 1000 times its mass in water. The mixture of sodium polyacrylate and leaked coolant creates a viscous or gelatinous semi-solid, thereby containing the coolant and preventing its spread among internal components 306 of chassis 304. The viscous or gelatinous semi-solid created by the mixture may be relatively easily removed from chassis 304 in the event of a coolant leak.

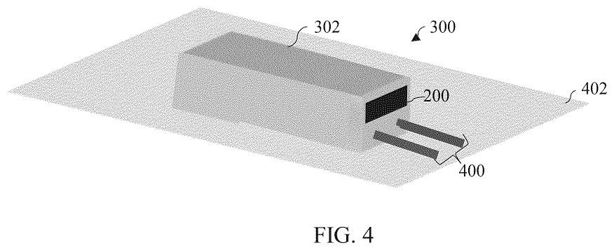

In certain embodiments, absorption layer 302 forms an absorbent pad on an inner surface of the bottom of chassis 304. In other embodiments absorption layer 302, as a dye-covered or dye-infused pliable material that may be configured to form a covering or shroud. Configured as a shroud, absorption layer 302 may cover or envelope all or some portions of the liquid cooling assembly. In FIG. 4, absorption layer 302 forms a shroud wrapped around one or cooling loops of the liquid cooling assembly.

FIG. 4 is a perspective view of leak mitigation system 300 according to at least one embodiment of the present disclosure. Illustratively, the cooling loop enshrouded by absorption layer 302 includes coolant ingress and egress 400 extending in parallel with a surface portion 402 of the information handling system chassis. OLS 200 illustratively mounts to a surface portion of the shroud formed by absorption layer 302. The dye covering or infused in absorption layer 302 is activated in response to the absorption layer being in contact with coolant leaked from the liquid cooling assembly in the presence of UV light emitted by OLS 200. The dye fluoresces when in contact with the liquid. OLS 200 is positioned within the shroud formed by absorption layer 302 to see any fluorescence that may occur within the shroud.

The shroud formed by absorption layer 302 may act as a waveguide preventing or mitigating visible or ultraviolet (UV) light created in response the fluorescence of the dye from leaving leak mitigation system 300. Confined within the shroud formed by absorption layer 302, the visible or UV light is magnified, thus enhancing the sensitivity of OLS 200. A greater amount of fluorescing light likely reaches OLS 200 as result of the shroud formed by absorption layer 302. The amount is greater than would otherwise be expected given the inverse square law, or so-called “inverse r-squared law,” whereby the light intensity decreases as the distance to the light source increases. Moreover, if the fluorescence is UV light, the shroud may provide an added benefit of partial eye protection by preventing or mitigating the escape of UV rays.

In other embodiments, adsorption layer 302 may be deposited on an adhesive layer attached to or sprayed onto an inner surface of the chassis. In certain embodiments, adsorption layer 302 may be formed of a powder. Absorption layer 302, in form of a powder, may be sprayed onto the adhesive layer. A dye infused in or added to absorption layer 302 may be a dry dye. The dry dye may be mixed in and sprayed on with adsorption layer 302 or may be sprayed on after the absorption layer is sprayed on. In some embodiments, the dye may be covered by an additional, protective layer. If covered, however, the dye is exposed in the event of a coolant leak. The expansion of adsorption layer 302 induced by the layer's contact with leaked coolant exposes the dye. Fluorescence of the dye in response to its exposure to the coolant indicates a potential coolant leak. Spray-on coating of the dye-covered or dye-infused adsorption layer 302 applies the layer to even difficult to reach places within chassis 304 and solves problems stemming from coolant wicking into hard to seal portions of the chassis, such as seams, thermal openings, narrow crevices, and the like.

Adsorption layer 302 in still other embodiments may be formed from adsorbent granules. In an example, the adsorbent granules may be easily dispersed with chassis 304 and provides a versatile and eco-friendly material for absorbing coolant leaks.

OLS 200, in various embodiments, may be retrofitted with a mounting assembly that mounts the OLS at a location within chassis 304. In some embodiments, OLS 200 may plug into a connector, such as a Platform Infrastructure Connectivity (M-PIC) specified PICPWR connector or a Peripheral Component Interconnect Express (PCIe) slot of a motherboard.

In each of the various embodiments described, multiple versions of OLS 200 may be placed within chassis 304 and may communicatively couple to a circuit, controller, microcontroller, processor or the like, which may be configured to identify, based on an OLS-generated signal, which OLS is sensing a potential leak. In this way, an actual or approximate location of the potential leak may be identified.

In an environment containing multiple information handling systems, such as a datacenter or server rack, each information handling system may be equipped with multiple versions of OLS 200, one per each information handling system. Each OLS in turn may communicatively couple with a circuit, controller, microcontroller, processor or the like that is configured to identify which OLS is sensing a potential coolant leak. In this manner, the specific information handling system in which the OLS indicates a potential coolant leak may be identified.

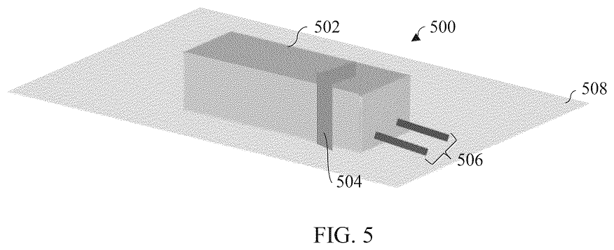

FIG. 5 is a perspective view of an example device 500 for mitigating coolant leaks within a chassis of a liquid-cooled information handling system according to at least one embodiment of the present disclosure. Device 500 illustratively includes pliable absorbent shroud 502 and strain gauge 504 connected with the shroud. Pliable absorbent shroud 502 is formed of a flexible absorbent material that wraps around or envelops all or a portion of a liquid cooling assembly within the chassis of the information handling system. Illustratively, in FIG. 5, pliable absorbent shroud 502 covers a portion of a cooling loop that includes coolant ingress and egress 506 extending in parallel with a surface portion 508 of the information handling system chassis.

Pliant absorbent shroud 502 absorbs coolant that leaks from the liquid cooling assembly. Pliable absorbent shroud 502, in certain embodiments, may be formed from an SAP. For example, in certain embodiments, the SAP is sodium polyacrylate. In other embodiments, pliable absorbent shroud 502 may be formed from different absorbent materials such as polypropylene-based fibers. Formed from sodium polyacrylate, pliable absorbent shroud 502 responds to a coolant leak by absorbing the leaked coolant and converting the liquid into a gelatinous or viscous semi-solid that may be easily removed from the chassis.

Strain gauge 504 is configured to detect a coolant leak. Operatively, strain gauge 504 detects a coolant leak in response to strain on the gauge when caused by an expansion of pliable absorbent shroud 502, which is induced by the contact of the shroud with the leaked coolant. In some embodiments, strain gauge 504 is formed on a printed circuit board that connects to pliant absorbent shroud 502. Note that connecting the strain gauge 504 to shroud 502 obviates the need for covering the shroud with dye or infusing dye into the material of the shroud. The effect of the expansion of pliable absorbent shroud 502 in response to absorbing coolant induces strain on strain gauge 504, thereby indicating a potential coolant leak.

In some embodiments, pliable absorbent shroud 502 may be elongated, extending over portions of the liquid cooling assembly. For example, pliable absorbent shroud 502 may extend over the pathway of the liquid cooling assembly tubing. Along the pathway, multiple strain gauges such as strain gauge 504 may be connected to pliable absorbent shroud 502 and spaced apart from one another. The strain gauges may communicatively couple to a circuit, controller, microcontroller, processor or the like, which is configured to identify based on receiving a gauge-generated signal which of the multiple strain gauges is experiencing a strain. In this way, an actual or approximate location of the potential leak may be identified.

In an environment containing multiple information handling systems, such as a datacenter or server rack, each information handling system may be equipped with a device such as device 500. Each device in turn may communicatively couple with circuit, controller, microcontroller, processor or the like that is configured to identify which device is experiencing a strain in response to receiving a gauge-generated signal. In this manner, the specific information handling system in which a potential leak is occurring may be identified.

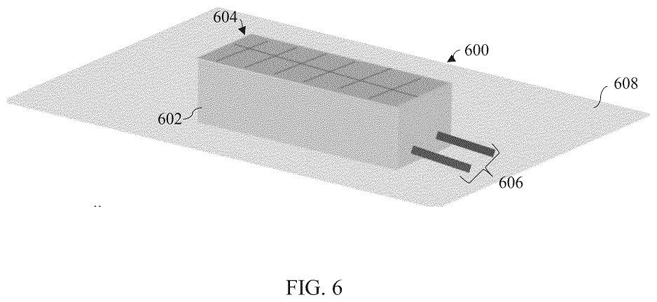

FIG. 6 is a perspective view of an example device 600 for mitigating coolant leaks within a chassis of a liquid-cooled information handling system according to at least one embodiment of the present disclosure. Device 600 illustratively includes pliable absorbent shroud 602 and one or more perforated dye-release packages 604 formed in a surface of the shroud. Pliable absorbent shroud 302 is configured to wrap or envelop all or portions of a liquid cooling assembly within the information handling system chassis. Illustratively, in FIG. 6, pliable absorbent shroud 602 envelops a cooling loop of the liquid cooling system. The cooling loop, as shown, includes coolant ingress and egress 606 extending in parallel with a surface portion 608 of the information handling system chassis.

Pliable absorbent shroud 602, in certain embodiments, is formed of an absorbent material. The material, in some embodiments, is an SAP, such as sodium polyacrylate. In other embodiments, pliable absorbent shroud 602 is formed from another absorbent material, such as such as polypropylene-based fibers.

Operatively, in the event of a coolant leak within the chassis, pliable absorbent shroud 602 absorbs the coolant. Pliable absorbent shroud 602 expands as the coolant is absorbed. One or more dye-release packages 604 are configured to burst in response to the pressure caused by the expansion. The bursting of one or more dye-release packages 604 exposes the dye released to the coolant. The dye fluoresces in contact with the coolant, and one or more OLSs within the chassis senses the fluorescing indicating a potential coolant leak.

In an environment containing multiple information handling systems, such as a datacenter or server rack, each information handling system may be equipped with a device such as device 600 along with one or more OLSs. Each OLS may communicatively couple with a circuit, controller, microcontroller, processor or the like that is configured to identify in which multiple information handling system dye has been released. Based on the release of the dye, the specific information handling system in which a potential leak has occurred or is occurring may be identified.

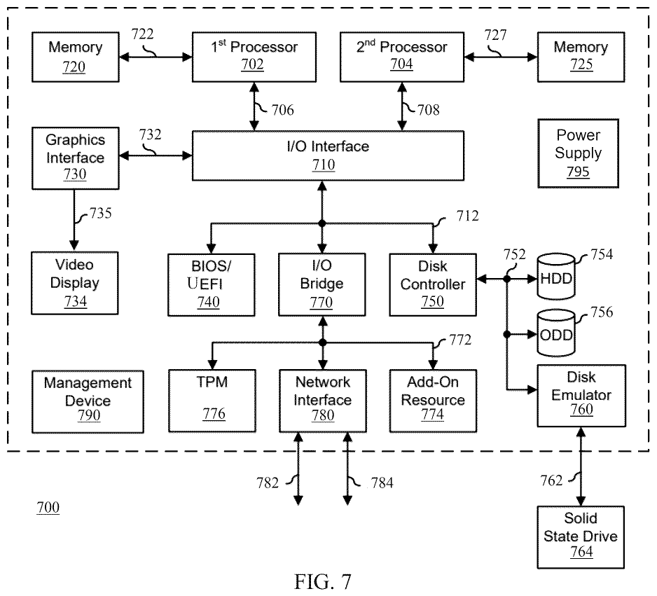

FIG. 7 shows a generalized embodiment of an information handling system 700 according to an embodiment of the present disclosure. Information handling system 700 may be one that includes a liquid cooling assembly, OLS, and leak mitigation system or device such as those of FIGS. 1-6. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable mediums for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below and operates to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 764, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 764, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732 and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 4394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712 or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof.

Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700.

Management device 790 can operate off a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

That which is claimed is:

1. A leak mitigation system for mitigating coolant leaks within a liquid-cooled information handling system, the leak mitigation system comprising:
an absorption layer infused with a dye and positioned within a chassis of the liquid-cooled information handling system, wherein the absorption layer is configured to absorb a coolant leaked from a liquid cooling assembly within the chassis; and
an optical leak sensor (OLS) also positioned within the chassis, wherein the OLS is configured to detect leaked coolant in response to fluorescence of the dye induced by contact with the leaked coolant when illuminated with ultraviolet light emitted by the OLS.

2. The leak mitigation system of claim 1, wherein the absorption layer is formed of a superabsorbent polymer.

3. The leak mitigation system of claim 2, wherein the superabsorbent polymer is sodium polyacrylate.

4. The leak mitigation system of claim 1, wherein the absorption layer is formed of a polypropylene-based synthetic fiber.

5. The leak mitigation system of claim 1, wherein the absorption layer forms an absorbent pad along a bottom surface of the chassis of the liquid-cooled information handling system.

6. The leak mitigation system of claim 1, wherein the absorption layer is deposited on an adhesive layer contacting a surface of the chassis.

7. The leak mitigation system of claim 6, wherein the adhesive layer is sprayed on to the surface.

8. The leak mitigation system of claim 7, wherein the dye is a dry dye sprayed on the adhesive layer with the absorption layer.

9. The leak mitigation system of claim 8, wherein the dye is covered by an additional sprayed-on layer and is configured to be exposed to coolant in response to an expansion of the absorption layer induced by contact of the absorption layer with the coolant.

10. The leak mitigation system of claim 1, wherein the absorption layer is formed by absorbent granules and dry dye dispersed within the chassis of the liquid-cooled information handling system.

11. The leak mitigation system of claim 10, wherein the absorption layer forms a shroud around at least one coolant loop of the of the liquid cooling assembly.

12. The leak mitigation system of claim 11, wherein the OLS is mounted inside the shroud.

13. A device for mitigating coolant leaks within a chassis of a liquid-cooled information handling system, the device comprising:
a pliable absorbent shroud configured to at least partially envelop portions of a liquid cooling assembly positioned within the chassis; and
a strain gauge connected to a portion of the pliable absorbent shroud, wherein the strain gauge is configured to detect a coolant leak in response to strain caused by a liquid-induced expansion of the pliable absorbent shroud.

14. The device of claim 13, wherein the pliable absorbent shroud is formed of superabsorbent polymer (SAP).

15. The device of claim 14, wherein the SAP is sodium polyacrylate.

16. The device of claim 13, wherein the pliable absorbent shroud is formed of a polypropylene-based synthetic fiber.

17. The device of claim 13, wherein the strain gauge is formed on a printed circuit board.

18. A device for mitigating coolant leaks within a chassis of a liquid-cooled information handling system, the device comprising:
a pliable absorbent shroud configured to at least partially envelop portions of a liquid cooling assembly positioned within the chassis; and
at least one perforated dye-release package formed in a surface of the pliable absorbent shroud, wherein the at least one perforated dye-release package is configured to burst in response to pressure caused by a liquid-induced expansion of the pliable absorbent shroud.

19. The device of claim 18, wherein the pliable absorbent shroud is formed of super-absorbent polymer (SAP).

20. The device of claim 18, wherein the pliable absorbent shroud is formed of a polypropylene-based synthetic fiber.
